(19) United States
(12) Patent Application Publication
(10) Pub. No.: US 2011/0169157 A1
(43) Pub. Date: Jul. 14, 2011

(54) SUBSTRATE AND FLIP CHIP PACKAGE WITH GRADATIONAL PAD PITCHES

(76) Inventor: Wen-Jeng FAN, Hukou Shiang (TW)

(21) Appl. No.: 12/686,966

(22) Filed: Jan. 13, 2010

(51) Int. Cl. H01L 23/482; H01L 23/488

(52) U.S. Cl. 257/692; 257/778; 257/737; 257/E23.014; 257/E23.023

(57) ABSTRACT

A flip-chip packaging substrate with gradational pad pitches for flip-chip jointing a bumped chip and a flip chip package utilizing the substrate are revealed. A plurality of connecting pads with non-equal pitches are disposed in an array on the substrate for jointing a plurality of equal-pitch bumps of a bumped chip. The pitches of the connecting pads are numbered according to the distance from a central line through a defined central point. When the defined pitch numbers increase by one, a substrate CTE compensation value is subtracted from the distance from the corresponding connecting pads to the center point so that the connecting pads are able to accurately align to the equal-pitch bumps during reflowing processes. Therefore, the expansion distance from the connecting pads of the substrate to the central point is equal to the expansion distance from the bumps of the bumped chip to the central point to avoid alignment shift between the bumps and the corresponding connecting pads due to CTE mismatch.

### FIELD OF THE INVENTION

The present invention relates to a semiconductor device and the related components, and more particularly to a substrate and a flip chip package with gradational pad pitches.

### BACKGROUND OF THE INVENTION

In the existing semiconductor industries, flip chip technology was known for better performance and reliability and has gradually replaced the conventional wire bonding technology to become the major packaging trend. The concept of flip chip technology is to dispose bumps on the bonding pads of a chip, then flip the bumped chip onto the substrate. After accurate alignment between the bumps and the substrate, the mechanical and electrical connections between the chip and the substrate can be completed by reflowing processes. In order to meet the fine pitch requirements, bumps for flip chip interconnection have been switching from solder bumps to metal pillar bumps such as Cu pillars so that bumps do not change shapes during reflowing processes. Solder is disposed on top of metal pillar bumps to joint to the connecting pads of the substrate. However, the bumps away from the center of a chip can not easily be aligned to the corresponding connecting pads of a substrate during reflowing processes where the alignment shift causes false soldering, empty soldering, poor soldering, or even wrong soldering.

As shown in FIG. 1A and FIG. 1B, a conventional flip chip substrate 110 has a top surface 111 including a flip-chip attaching area 112 where a plurality of connecting pads 113 are disposed in an array within the flip-chip attaching area 112. In the existing flip-chip assembly technology, the connecting pads 113 of the substrate 110 can accurately align to the bumps of a bumped chip under room temperature, however, since the substrate has a larger Coefficient of Thermal Expansion (CTE), therefore, the thermal expansion of the substrate 110 during reflowing processes is much larger than the one of a chip causing alignment shift between the connecting pads 113 and the corresponding bumps of a chip leading to electrical connection failure between the substrate and the chip.

### SUMMARY OF THE INVENTION

The main purpose of the present invention is to provide a flip-chip packaging substrate with gradational pad pitches to avoid alignment shift between the bumps of a chip and the corresponding connecting pads of a substrate due to CTE mismatch during reflowing processes.

According to the present invention, a flip-chip packaging substrate with gradational pad pitches for flip-chip jointing a bumped chip is revealed. The substrate has a top surface including a flip-chip attaching area within which a plurality of connecting pads with non-equal pitches are disposed in an array where the pitches of the connecting pads are numbered according to the distance from a central line through a defined central point. When the defined pitch numbers increase by one, a substrate CTE compensation value is subtracted from the distance from the corresponding connecting pads to the center point so that the connecting pads are able to accurately align to the equal-pitch bumps of a bumped chip. A flip chip package utilizing the substrate is also revealed in the present invention.

A flip-chip packaging substrate with gradational pad pitches according to the present invention has the following advantages and functions. Through the specific combination between the substrate and the non-equal pitches of the connecting pads as a technical mean, a substrate CTE compensation value is added to the distance from the corresponding connecting pads to the center point so that the connecting pads are able to accurately align to the equal-pitch bumps of a bumped chip during reflowing. Therefore, the CTE compensation distance from the connecting pads of the substrate to the central point matches to the CTE compensation distance from the bumps of a chip to the central point to avoid alignment shift due to CTE mismatch between the chip and the substrate.

### DESCRIPTION OF THE DRAWINGS

FIG. 1A and FIG. 1B are a cross-sectional view and a top view of a conventional flip-chip packaging substrate.

FIG. 2A and FIG. 2B are a cross-sectional view and a top view of a flip-chip packaging substrate with gradational pad pitches according to the first embodiment of the present invention.

FIG. 3 is a cross-sectional view of the flip-chip packaging substrate and an aligned bumped chip before reflowing processes according to the first embodiment of the present invention.

FIG. 4 is a cross-sectional view of the flip-chip packaging substrate and an aligned bumped chip during reflowing processes before bonding according to the first embodiment of the present invention.

FIG. 5 is a cross-sectional view of the flip-chip packaging substrate and the aligned bumped chip during reflowing processes after bonding according to the first embodiment of the present invention.

FIG. 6 is a table listing the pitch numbers corresponding to the distances from the bumps to the central point and the distances from the connecting pads to the central point according to the first embodiment of the present invention.

FIG. 7 is a plot showing a linear direct proportion relationship between the pitch numbers and the corresponding distances from the connecting pads to the central point according to the first embodiment of the present invention.

FIG. 8 is a cross-sectional view of a flip chip package utilizing the substrate according to the first embodiment of the present invention.

FIG. 9 is a cross-sectional view of another flip-chip packaging substrate with gradational pad pitches according to the second embodiment of the present invention.

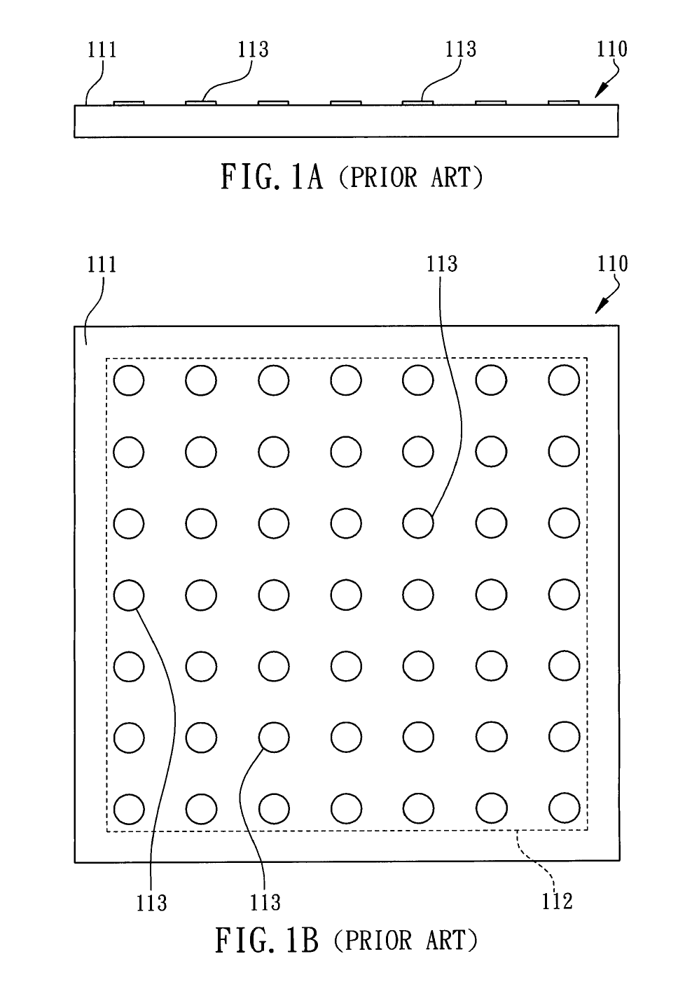

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

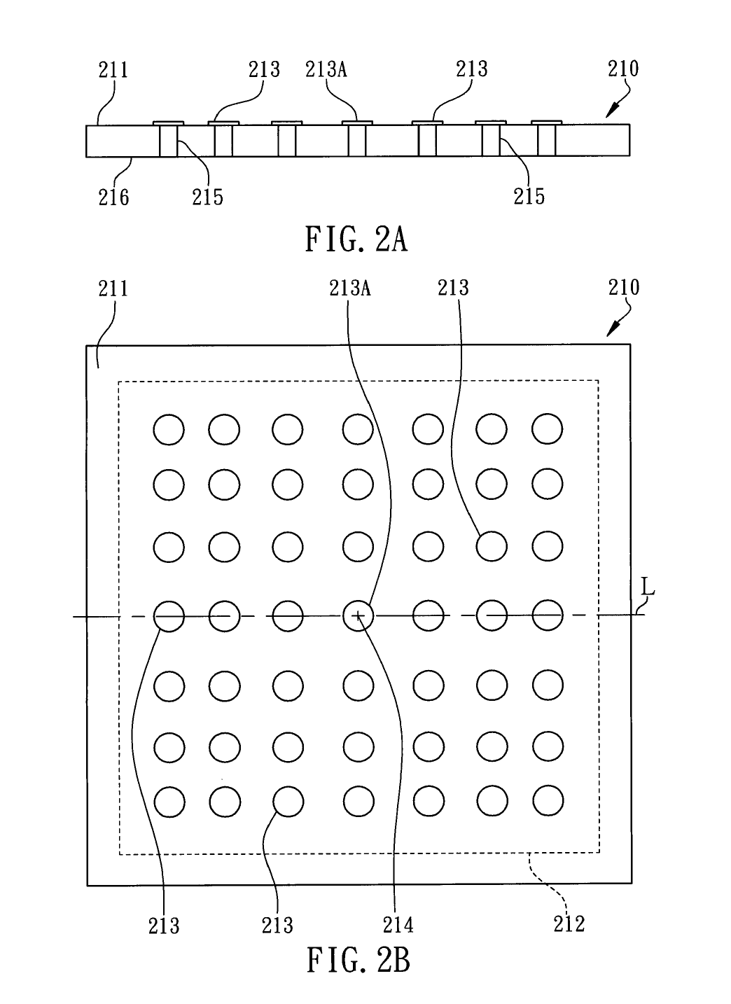

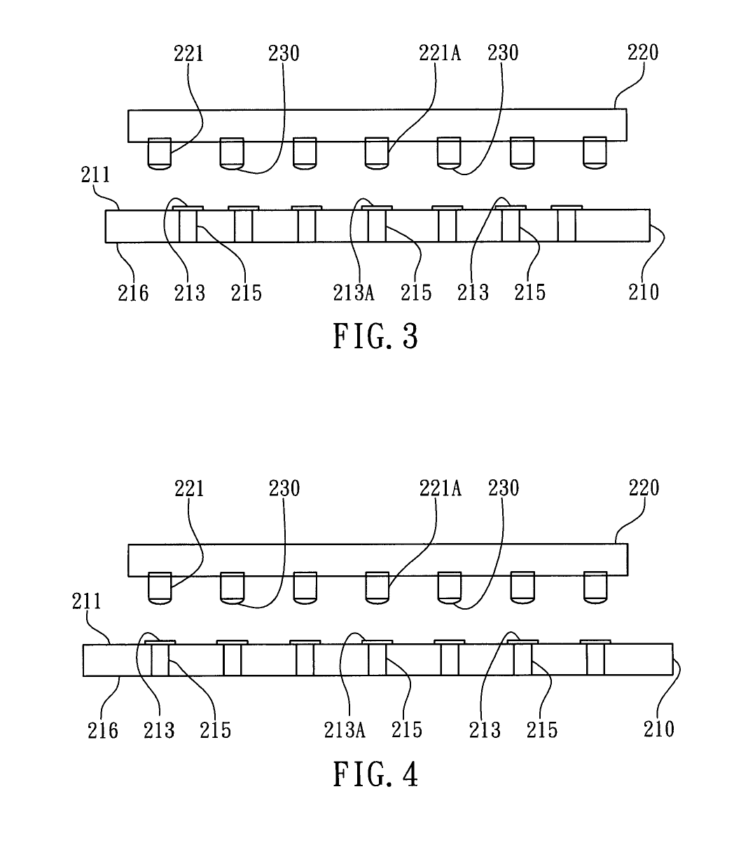

According to the first embodiment of the present invention, a flip-chip packaging substrate 210 with gradational pad pitches is illustrated in FIG. 2A and FIG. 2B for a cross-sectional view and a top view. A bumped chip 220 as shown in FIG. 3 is flip-chip jointing to the flip-chip packaging substrate 210. The substrate 210 has a top surface 211 including a flip-chip attaching area 212 which is a chip-covering area matching to the footprint of the bumped chip 220. A plurality of non-equal pitches of the connecting pads 213 are disposed within the flip-chip attaching area 212 where the pitches of the connecting pads 213 are numbered according to a straight line L through the central point 214 of the flip-chip attaching area 212 to define the pitch number (n). The central point defined as the central point of the flip-chip attaching area 212 can be a virtual point, a fixed point, or a bump. In the present embodiment, the connecting pads 213 include a central connecting pad 213A located right at the central point 214 for easy recognition of the position of the central point 214. Moreover, as shown in FIG. 2B, the line L can be in X-axis or in Y-axis or in the diagonal axis of the flip-chip attaching area 212.

As the defined pitch number (n) increases, the distance between the corresponding connecting pads 213 to the central point 214 subtracts a substrate CTE compensation value so that the connecting pads 213 are able to accurately align to the equal-pitch bumps 221 of the bumped chip 220 during reflowing processes as shown in FIG. 4. In the present embodiment, the ideal setting value of bump pitch is 0.1 mm and the substrate CTE compensation value is 0.000272 mm where the actual implementation and the corresponding calculation equation is described in detail later.

In the present embodiment, the connecting pads 213 have the same soldering areas and shapes without specific changing the shapes of the connecting pads 213 to achieve accurate alignment. To be more specific, the pitches between the connecting pads 213 can not be greater than 0.1 mm to meet the flip-chip jointing requirement of fine-pitch bumps. Furthermore, the peripheries of the connecting pads 213 can be exposed to be non-solder-mask defined (NSMD) type. Moreover, the flip-chip packaging substrate 210 further comprises a plurality of plated through holes 215 disposed under the connecting pads 213 to electrically and mechanically connect with the corresponding connecting pads 213 to avoid peeling of the connecting pads 213 from the substrate 210 due to expansion and contraction of the substrate 210. The connecting pads 213 are electrically connected to the bottom surface 216 of the substrate 210. A bottom circuitry not shown in the figure can be disposed on the bottom surface 216 according to the product requirements to electrically connect the plated through holes 215 to external terminals for external electrical connections.

As shown in FIG. 3, the connecting pads 213 and the corresponding equal-pitch bumps 221 can not be aligned to each other in the design stage. In a preferred embodiment, the equal pitch of the bumps 221 can be 0.1 mm so that the pitch between two adjacent connecting pads 213 is smaller than the pitch between two adjacent equal-pitch bumps 221. Preferably, the substrate CTE compensation value is a linear direct proportion value so that the pitch between the connecting pads 213 gradually decreases as the distance from the central point 214 increases. In other words, the largest number of the pitch number (n) have the smallest pitch between two adjacent connecting pads 213 to overcome extra substrate CTE expansion characteristics during reflowing processes.

As shown in FIG. 4, the bumped chip 220 and the substrate 210 gradually expand as the reflow temperature gradually increases during reflowing processes. To be more specific, since the CTE of the substrate 210 is larger than the CTE of the bumped chip 220, therefore, the outward expansion of the substrate 210 due to CTE is much larger than the outward expansion of the bumped chip 220 so that the connecting pads 213 of the substrate 210 are gradually aligned to the corresponding equal-pitch bumps 221 due to CTE expansion. Furthermore, at reflow temperature of 245° C., the expansion distance from the connecting pads 213 of the substrate 210 to the central point 214 is the same as the expansion distance from the equal-pitch bumps 221 to the central point 214 so that the connecting pads 213 are accurately aligned to the corresponding equal-pitch bumps 221 to enhance the following flip-chip jointing processes.

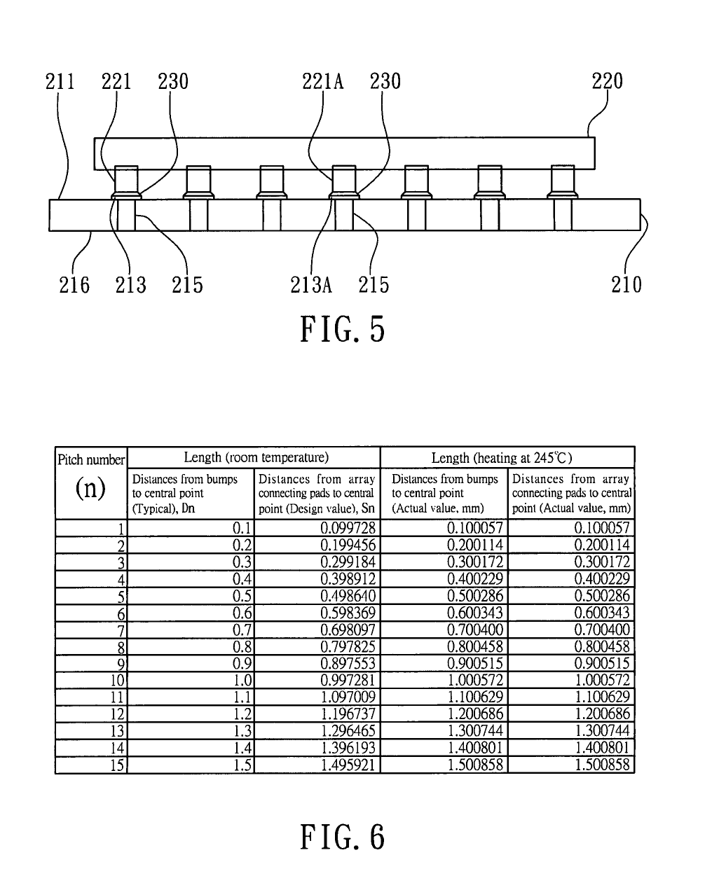

In the present invention, as shown in FIG. 5, during soldering processes under reflow temperatures, the connecting pads 213 of the substrate 210 are accurately aligned to the equal-pitch bumps 221 of the bumped chip 220. Even though the dimensions of the substrate 210 and the bumped chip 220 become larger due to thermal expansion, however, the connecting pads 213 of the flip-chip packaging substrate 210 of the present invention have been designed to be non-equal pitches during the design stage (as shown in FIG. 2A and FIG. 2B) where the CTE mismatch between the substrate 210 and the bumped chip 220 has been considered in the design of the substrate 210 by defining pitch number (n) of the connecting pads 213 from the central point 214. When the pitch number (n) increases by one, the distance from the connecting pads 213 to the central point 214 is subtracted a substrate CTE compensation value. Therefore, the distances from the connecting pads 213 to the central point 214 during flip-chip jointing processes under reflow temperature are equal to the distances from the corresponding equal-pitch bumps 221 to the central point 214 to reach thermal expansion equilibrium to completely avoid alignment shift between the connecting pads 213 and the equal-pitch bumps 221 due to CTE mismatch.

As shown in FIG. 6, the second and third columns from the left of the table are the lengths under room temperature where “Dn” is the initial distance from the equal-pitch bumps 221 to the central point and “Sn” is the design distance from the connecting pads 213 to the central point 214. As shown in FIG. 3, the connecting pads 213 of the substrate 210 can not align to the equal-pitch bumps 221 of the bumped chip 2210 during the initial design stage. Moreover, the forth and fifth columns from the left of the table are the lengths when heating to the reflow temperature of 245° C. It can clearly be seen that the distance from the connecting pads 213 to the central point 214 is exactly equal to the distance from the equal-pitch bumps 221 to the central point 214 as shown in FIG. 4 and FIG. 5.

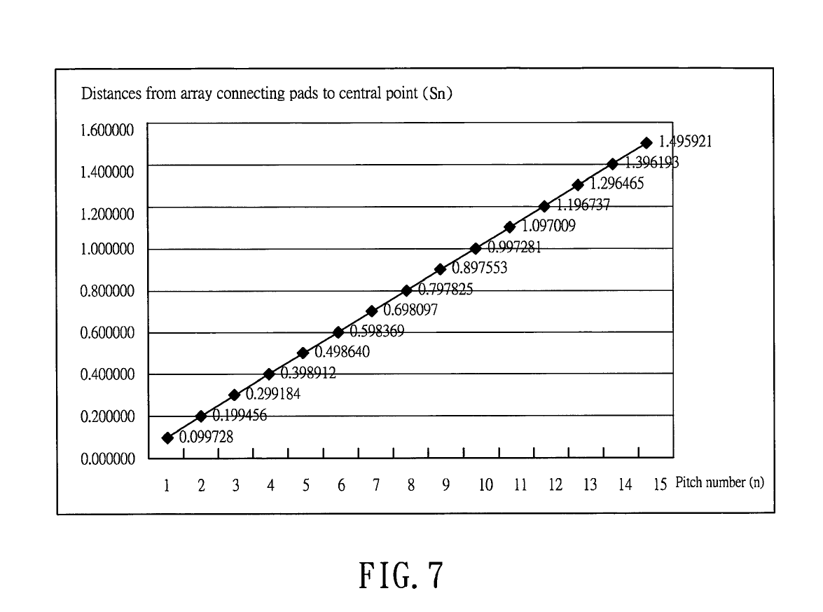

As shown in FIG. 7, the pitch number (n) and the distance (Sn) are in linear direct proportional relationship where “Sn” is the distance from the connecting pads 213 to the central point 214. To be more specific, the distance “Sn” from the connecting pads 213 to the central point 214 can be calculated from a specific equation such as “Sn=(bump pitch×n×(1+chip's CTE×(reflowing temperature−room temperature)))/(1+substrate's CTE×(reflowing temperature−room temperature)) where the temperature unit of “reflowing temperature” and “room temperature” is centigrade (° C.), moreover, the setting temperature of reflowing temperature is 245° C. and the room temperature is 25° C. In the present embodiment, the chip's CTE is 2.60 E-06 (1/° C.) and the substrate's CTE is 1.50 E-0.5 (1/° C.).

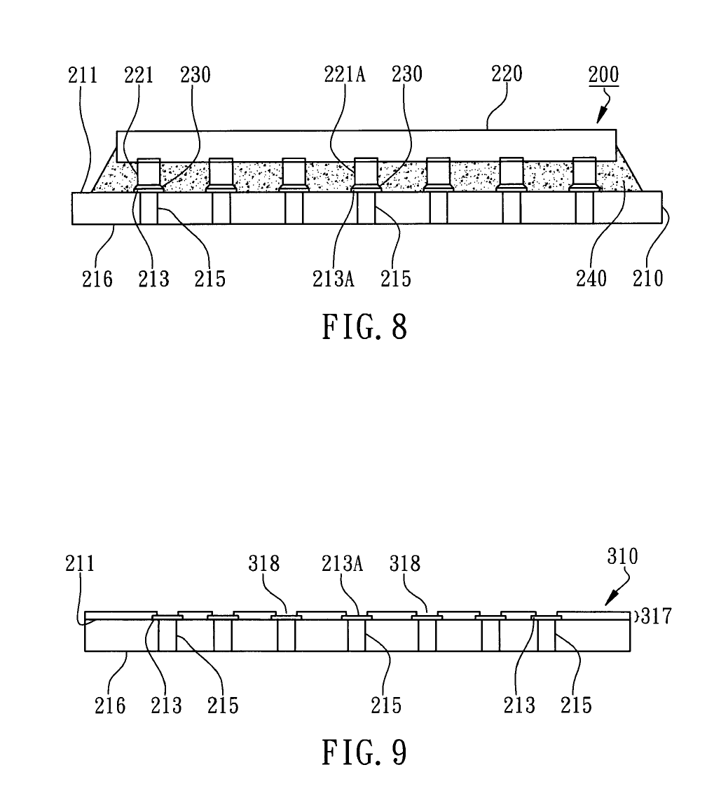

A flip chip package 200 is also revealed in the present invention as shown in FIG. 8, comprising the above described flip-chip packaging substrate 210 and the bumped chip 220 where the bumped chip 220 has a plurality of equal-pitch bumps 221 to joint to the corresponding connecting pads 213. To be more specific, the equal-pitch bumps 221 comprise a central bump 221A where the central bump 221A is aligned to the central connecting pad 213A. In the present embodiment, the flip chip package 200 further comprises a plurality of solder materials 230 where the equal-pitch bumps 221 are metal pillars such as copper pillars and are jointed to the corresponding connecting pads 213 by the solder materials 230. In a preferred embodiment, the material of the equal-pitch bumps 221 is copper. Furthermore, the pitch of the equal-pitch bumps 221 is 0.1 mm at room temperature in the initial design stage and the pitches of the connecting pads 213 are not greater than 0.1 mm, i.e., the pitch of two adjacent connecting pads 213 is smaller than the pitch of two adjacent equal-pitch bumps 221. Moreover, the flip chip package 200 further comprises an underfill material 240 filling the gap between the substrate 210 and the bumped chip 220 to encapsulate the equal-pitch bumps 221, the connecting pads 213 and the solder materials 230. The underfill material 240 is configured to enhance the overall package strength and soldering interfaces so that the substrate 210 and the bumped chip 220 can firmly joint together.

According to the second embodiment of the present invention, another flip-chip packaging substrate 310 is illustrated in FIG. 9 for a cross-sectional view. The major components and the corresponding described numbers are followed the ones in the first embodiment without further description. The substrate 310 has a top surface 211 including a flip-chip attaching area 212 where a plurality of non-equal pitches of connecting pads 213 are disposed within the flip-chip attaching area 212. A substrate CTE compensation value is subtracted from the distance of the corresponding connecting pads 213 to the central point 214 to enable accurate alignment between the connecting pads 213 and the corresponding equal-pitch bumps 221 of the bumped chip 220 during reflowing processes.

In the present embodiment, the substrate 310 further comprises a solder mask 317 formed on the top surface 211 of the substrate 310 where the solder mask 317 has a plurality of opening 318 aligned to the corresponding connecting pads 213 to cover the peripheries of the connecting pads 213 to make the connecting pads 213 become solder-mask defined (SMD) type to avoid peeling of the connecting pads 213 during the expansion and contraction of the substrate 210. Preferably, a plurality of plated through holes 215 are disposed under the corresponding connecting pads 213 to electrically and mechanically connect with the corresponding connecting pads 213.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A flip-chip packaging substrate for flip-chip jointing a bumped chip, the substrate having a top surface including a flip-chip attaching area within which a plurality of connecting pads with non-equal pitches are disposed in an array, wherein the pitches of the connecting pads are numbered according to the distance from a central line through a defined central point of the flip-chip attaching area, when the defined pitch numbers increase by one, a substrate CTE compensation value is subtracted from the distance from the corresponding connecting pads to the center point so that the connecting pads are accurately aligned to a plurality of equal-pitch bumps of the bumped chip during reflowing.

2. The substrate as claimed in claim 1, wherein all the connecting pads have the same soldering areas and shapes.

3. The substrate as claimed in claim 1, wherein the pitches of the connecting pads are not greater than 0.1 mm.

4. The substrate as claimed in claim 1, wherein the peripheries of the connecting pads are exposed to be NSMD type.

5. The substrate as claimed in claim 4, further comprising a plurality of plated through holes disposed under the corresponding connecting pads to electrically and mechanically connect with the corresponding connecting pads.

6. The substrate as claimed in claim 1, further comprising a solder mask formed on the top surface of the substrate and having a plurality of opening aligned to the corresponding connecting pads wherein the solder mask covers the peripheries of the connecting pads to make the connecting pads become SMD type.

7. The substrate as claimed in claim 6, further comprising a plurality of plated through holes disposed under the corresponding connecting pads to electrically and mechanically connect with the corresponding connecting pads.

8. The substrate as claimed in claim 1, wherein the connecting pads include a central connecting pad located at the central point.

9. The substrate as claimed in claim 1, wherein the pitches of the connecting pads become smaller as the distance of the connecting pads from the central point become larger.

10. A flip chip package comprising a flip-chip packaging substrate as claimed in claim 1 and a bumped chip, wherein the bumped chip has a plurality of equal-pitch bumps jointed to the corresponding connecting pads.

11. The package as claimed in claim 10, further comprising a plurality of solder materials, wherein the equal-pitch bumps are metal pillar and are jointed to the corresponding connecting pads by the solder materials.

12. The package as claimed in claim 11, further comprising an underfill material filling the gap between the substrate and the bumped chip to encapsulate the equal-pitch bumps, the connecting pads and the solder materials

13. The package as claimed in claim 10, wherein all the connecting pads have the same soldering areas and shapes.

14. The package as claimed in claim 10, wherein the pitches of the connecting pads are not greater than 0.1 mm.

15. The package as claimed in claim 10, wherein the peripheries of the connecting pads are exposed to be NSMD type.

16. The package as claimed in claim 15, further comprising a plurality of plated through holes disposed under the corresponding connecting pads to electrically and mechanically connect with the corresponding connecting pads.

17. The package as claimed in claim 10, further comprising a solder mask formed on the top surface of the substrate and having a plurality of opening aligned to the corresponding connecting pads wherein the solder mask covers the peripheries of the connecting pads to make the connecting pads become SMD type.

18. The package as claimed in claim 17, further comprising a plurality of plated through holes disposed under the corresponding connecting pads to electrically and mechanically connect with the corresponding connecting pads.

19. The package as claimed in claim 10, wherein the connecting pads include a central connecting pad located at the central point.

20. The package as claimed in claim 10, wherein the pitches of the connecting pads become smaller as the distance of the connecting pads from the central point become larger.
